(19) United States
(12) Patent Application Publication
(10) Pub. No.: US 2024/0339999 A1
(43) Pub. Date: Oct. 10, 2024

(54) METHOD FOR THE MOMENTARY-VALUE-DEPENDENT ACTUATION, IN REAL TIME, OF A TOPOLOGICAL SEMICONDUCTOR SWITCH FOR A POWER ELECTRONICS SYSTEM

(71) Applicant: ZF Friedrichshafen AG, Friedrichshafen (DE)

(72) Inventors: Teresa Bertelshofer, Bayreuth (DE); Michael Meiler, Bayreuth (DE)

(73) Assignee: ZF Friedrichshafen AG, Friedrichshafen (DE)

(21) Appl. No.: 18/579,150

(22) PCT Filed: Jul. 11, 2022
(86) PCT No.: PCT/EP2022/069314

§ 371 Date: Jan. 12, 2024

(30) Foreign Application Priority Data
Jul. 12, 2021 (DE) 10 2021 207 311.5

(51) Int. Cl. H03K 17/12; H03K 17/567

(52) U.S. Cl. CPC H03K 17/122; H03K 17/567; H03K 2217/0027

(57) ABSTRACT

A method for momentary value-dependent actuation of a topological semiconductor switch for a power electronics system in real time is proposed, wherein the topological semiconductor switch is divided into at least two groups (A, B, N) of power semiconductors, which are made of different semiconductor materials and/or different types of semiconductors. A negative and positive switching threshold are also defined. A momentary value for at least one variable physical value (S1) is recorded at predetermined times that describes the operating state of the system, and compared with the switching thresholds, wherein it is decided on the basis of the results, which of the at least two groups of power semiconductors are actuated in order to conduct the output electricity.

The present invention relates to the field of electric mobility, in particular a method for momentary value-dependent actuation of a topological semiconductor switch for a power electronics system.

Semiconductor transistors are used in numerous fields as electronic switches and referred to as semiconductor switches. This is because a semiconductor switch can be switched back and forth between two states. A first state is when it is switched on. The semiconductor switch can conduct electricity in this state, and behave like a low resistor or diode in the forward direction. The other state is when it is off. In this state, the semiconductor switch can receive a voltage of, e.g., 400V or 800V.

Semiconductor switches can be switched on and off very quickly and efficiently. This switching is the basis for many electronic circuits, e.g. power supplies, converters, rectifiers, and inverters.

A control port, the so-called gate driver, is what makes it possible to switch the semiconductor switch off and on. There are two basic types of semiconductor switches. These are voltage-controlled semiconductor switches and current-controlled semiconductor switches. For the voltage-controlled semiconductor switches, the voltage must be above or below a defined level, e.g. +5V or −3V, to switch the semiconductor on or off. With current-controlled semiconductor switches, the current must be above or below a defined current to switch the semiconductor switch on or off.

A control circuit with which the semiconductor switch is switched on and off is needed for both versions.

Control circuits or control assemblies have an input side and an output side. The input side has at least one signal value that contains information regarding whether the semiconductor switch is to be switched on or off. The input and output sides of the control assembly can also be insulated from one another. The output side has at least one output signal, which responds to voltage levels, amperages, etc. such that the semiconductor switch can be actuated with this signal.

The applicant has already proposed an assembly for a topological switch that has at least two power semiconductors, in particular power transistors, the semiconductor switch for which has at least one first power semiconductor with a first semiconductor material, and at least one second power semiconductor with a second semiconductor material.

These actuation assemblies can only be used for topological semiconductor switches that are made of the same types of semiconductor switches. With a topological switch comprising a parallel connection of different semiconductor materials with large bandgaps, e.g. SiC, GaN, Si, etc. and/or different semiconductor types, e.g. MOSFET (metal-oxide-semiconductor field-effect transistor), IGBT (insulated-gate bipolar transistor), JFET (junction field-effect transistor), etc. it is not possible to actuate the different semiconductors separately with this assembly, because each type of semiconductor must have a separate actuation signal.

The object of the present invention is to overcome this problem. This problem is solved by the invention with the features of the independent claims. Advantageous embodiments are the subject matter of the dependent claims.

For this, a method for the momentary value-dependent actuation of a topological semiconductor switch for a power electronics system in real time is proposed, in which the topological semiconductor switch is divided into two groups of power semiconductors that are made of different semiconductor materials and/or different types of semiconductors. A negative switching threshold and positive switching threshold are also defined. A momentary value of at least one variable physical value that describes the operating state of the system is detected at predetermined times and compared with the switching thresholds, and it is then decided on the basis of the results, which of the at least two groups of power semiconductors are to be switched on to conduct the output electricity.

By using physical values that are relevant to the system that is being operated, e.g. an electric motor in a vehicle, which are recorded as momentary values, i.e. in real time, and determining upper and lower switching thresholds, the determination of which power semiconductor should be actuated for the required performance is improved, and a corresponding actuation signal is output. The decision is instantaneous, i.e. in real time. Consequently, different types of power semiconductors that are actuated independently and can also be made of different materials and/or have different designs, can be used to form a single topological switch. This results in an optimization of the actuation of the power semiconductors that are used in order to make better use of their properties, and the properties of different groups of power semiconductors can be combined for greater efficiency.

In one embodiment, if all of the momentary values of the physical values within a given time interval are between the switching thresholds, switching to another group does not take place. If the measured values, i.e. the momentary values, for a given time period are between the positive and negative switching thresholds, switching to another group does not take place. Advantageously, this range is therefore the most optimal range for the properties of the group that is active in this range. Advantageously, the more efficient group of power semiconductors within this range is selected.

If the physical value falls below the negative switching threshold, switching from the current group to another group, or adding at least one other group to the active group of the topological semiconductor switches, takes place in one embodiment in order to conduct the output electricity. If the positive switching threshold is exceeded, switching from the current group to another group, or adding at least one other group to the active group of topological switches takes place in one embodiment. Consequently, different groups of power semiconductors, which also have different properties, or strengths and weaknesses, depending on the operating state, can be used in a targeted manner in order to make use of their strengths for the respective application.

In one embodiment, the at least one variable physical value is a current value, which fluctuates between positive and negative values in waves over time, and if all of the momentary values of the physical value lie between the switching thresholds during a specific time period, there is no switching to another group, or any adding of at least one other group to the active group.

In one embodiment, there is hysteresis near at least one of the switching thresholds. By providing hysteresis at the switching threshold, undefined behavior can be prevented there, e.g. toggling between two groups.

In one embodiment, the semiconductor materials are selected from a group comprising at least Si, SiC, and GaN. In another embodiment, the semiconductor switches are transistors such as a MOSFET, IGBT, or JFET.

In one embodiment, the switching thresholds are determined on the basis of the observed physical values.

In one embodiment, switching signals for actuating the topological switches are generated and the momentary value is linked to the switching signal to obtain an actuation signal, in order to actuate the selected group. This linking of the input signal to the switching threshold forms a logical link, in particular a conjunctive link. Consequently, the decision regarding which group is to be actuated is an additional part of the actuation strategy for the topological semiconductor switch.

There is also an analog circuit that is configured to execute the method in real time. There are numerous ways of implementing the method using analog circuits that can compare the momentary value with the switching threshold and decide whether or not to switch in real time.

An electronic module for actuating an electric drive in a vehicle is also proposed, in which the electronic module contains an inverter with the circuit described above. An electric drive for a vehicle that contains this electronic module and a vehicle that contains this electric drive are also proposed.

Further features and advantages of the invention can be derived from the following description of exemplary embodiments of the invention in reference to the drawings showing details of the invention, and from the claims. The individual features can be realized in and of themselves or in numerous arbitrary combinations to obtain different variations of the invention.

Preferred embodiments of the invention shall be explained in greater detail below in reference to the drawings. Therein:

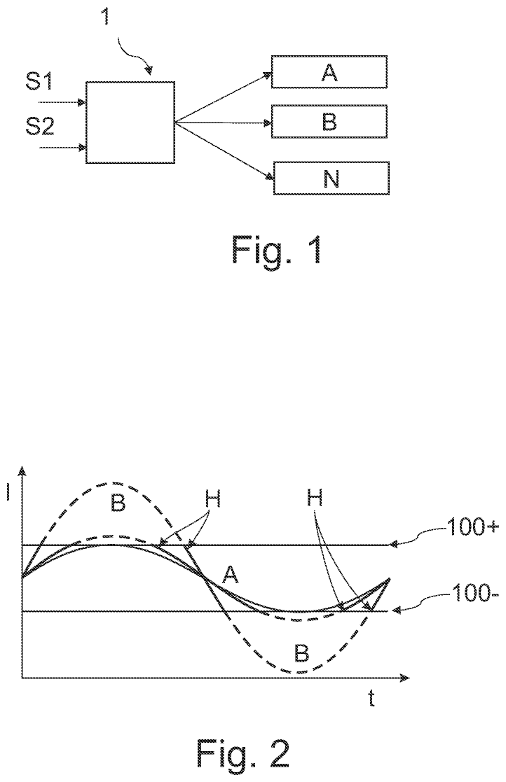

FIG. 1 shows an abstract illustration of the method for actuation of topological semiconductor switches based on momentary values according to one embodiment of the present invention; and

FIG. 2 shows a schematic illustration of an implementation of the method according to one embodiment of the present invention.

The reference symbols are used for identical elements and functions in the following description of the drawings.

Inverters, or power converters, require a power module or semiconductor package for converting direct current from a battery into alternating current. The power module contains topological switches with semiconductor transistors functioning as power transistors, which are used to control the currents and to generate the alternating current. Power transistors have numerous different designs. These include MOSFETS (metal-oxide-semiconductor field-effect transistor) and IGBTs (insulated-gate bipolar transistor). The semiconductor material used therein can be silicon (Si), silicon carbide (SiC), gallium nitride (GaN) or any other semiconductor material. Materials with a wide bandgap are preferred.

In order to comply with stricter fleet efficiency goals in the field of electric mobility, it is necessary to increase the efficiency of the inverter by using novel semiconductor technologies, e.g. SiC MOSFETs. The semiconductor surface for normal, e.g. average, driving is excessive, because the operating point of relevance is rarely reached. The problem is that the semiconductor surfaces in newer technologies (wide bandgap semiconductors (WGB)), which are more efficient, (e.g. SiC or GaN) are more expensive than conventional silicon. With conventional systems that contain semiconductors made of a less expensive material (e.g. silicon), the size can be determined on the basis of the operating point relevant to the design, allowing for safety margins, because the costs in relation the surface area of the semiconductor are relatively low compared to those for WGB materials. When WGB semiconductors are used in a conventional design, they not only take up more space, they are also more expensive. It is therefore necessary to find the optimal balance between the best possible technologies and the lowest costs.

For this reason, the semiconductors are designed by selecting the type of semiconductor and semiconductor material based on the application, i.e. the objective. Semiconductor transistors with silicon are more conductive with stronger currents, while semiconductor transistors with silicon carbide also exhibit this property with weaker currents. This is one way of optimizing the supply of power with respect to power consumption.

It has not yet been possible to actuate different power semiconductors connected in parallel that are made of different semiconductor materials and/or have different types of semiconductors with a single topological semiconductor switch. This would contribute, however, to an optimization of the use of the power semiconductor in question. To change this, the following method is proposed.

The invention results in method for momentary value-dependent actuation of a topological semiconductor switch for a power electronics system, shown in an abstract form in FIG. 1, which is advantageously carried out with an analog circuit 1 because of the requirement of real-time capability, which is shown as a black box due to the multifaceted implementation. The topological semiconductor switch has at least two power semiconductors connected in parallel, in particular power transistors. The topological semiconductor switches are divided into at least two groups A, B, . . . , N. These groups A, B, . . . , N are made of different semiconductor materials and/or different types of semiconductors. The semiconductor materials can be Si, SiC, GaN, etc. Semiconductor materials with a wide bandgap are advantageous. The types of semiconductors can be MOSFET, IGBT (with freewheeling diodes), RC-IGBT, JFET, etc. Groups A, B, . . . , N can also be cascode circuits. By way of example, one of the groups A, B can be a SiC MOSFET, and one of the other groups A, B, . . . , N can be a silicon IGBT with antiparallel freewheeling diodes.

The objective is to be able to actuate each of the groups A, B, . . . , N separately. For this, a positive switching threshold 100+ and a negative switching threshold 100− are defined. The switching thresholds 100+ and 100− are defined on the basis of the observed physical value S1, e.g. the current value I.

As long as the currently recorded measurement value, i.e. the momentary value, lies within the range or bandwidth between the two thresholds 100+ and 100−, switching to another group A, B, . . . , N does not take place.

If the value exceeds the positive switching threshold 100+ or falls below the negative switching threshold 100−, switching from the active group (Group A in FIG. 2) to another group (Group B in FIG. 2) of topological semiconductor switches takes place, in order to conduct the output electricity. Alternatively, at least one other group A, B, . . . , N can be added to the active group A, B, . . . , N (not shown).

FIG. 2 shows a concrete example of the implementation of the method. This shows a graph plotting current I over time t. The maximum acceptable current values (positive and negative, due to the positive and negative current waves) are defined as the switching thresholds 100+ and 100−. Switching to another group from the group lying in the range between the switching thresholds 100+ and 100− with a higher efficiency, group A in FIG. 2, first takes place if the value exceeds or falls below the associated switching threshold 100+ or 100−. This means that as long as all of the current measurement values (momentary values) for the current I within a given (measurement) time interval, advantageously a period, lie between the switching thresholds, 100+ and 100−, switching from group A to B does not take place. Group A consequently provides the entire output electricity within the period in question. If the value exceeds the limit value, i.e. the switching threshold 100+ during the positive current wave, switching from group A to group B takes place. Group B then provides the output current during this period. The same is the case if the value falls below the limit value, the switching threshold 100− during the negative half-wave.

To prevent an undefined behavior at the switching thresholds 100+ and 100−, there can be a hysteresis H at one or both of the switching thresholds 100+, 100−. Consequently, if the value falls below the switching threshold 100+ in the positive half-wave within a defined tolerance range, the output current continues to be provided by group B (and switching to group A does not take place). Analogously, if the value exceeds the switching value 100− in the negative half-wave within a defined tolerance range, the output current also continues to be provided by group B (and switching to group A does not take place).

One advantage of the strategy for switching between group A and B presented here is the continuous exploitation of the higher efficiency of group A, which is made of SiC semiconductors, for example.

At least one more group can be determined, in addition to the selected groups, i.e. added thereto, for conducting the output electricity. Numerous groups can therefore be combined and actuated simultaneously. By constantly using the more efficient groups, e.g. group A, at defined segments of the current wave, the level of efficiency only approaches the lower efficiency of group B.

Further, by using an angle sensor, e.g. a rotor position sensor, the point in time for the switching can be based on an angle.

Conventional controller switching signals S2 are determined for actuating the topological switch. The momentary value (the current measurement value for the observed physical value S1) is linked to this switching signal S2 to obtain an actuation signal with which the selected group A, B is actuated. The linking of the input signal to the switching thresholds 100+, 100− forms a logical link, in particular a conjunctive link.

The actuation assembly can contain a potential separation between the input and output side (not shown). This results in a galvanic separation of a high voltage circuit from a low voltage circuit.

The method is advantageously carried out by an analog circuit 1, because the necessary, quick, or instantaneous decisions can be made therewith. The method can therefore be carried out in real time.

The proposed method can be used with inverters in the field of electric mobility, i.e. for an electric drive.

### LIST OF REFERENCE SYMBOLS

1 analog circuit
100+, 100− positive, negative switching thresholds
A, B power semiconductor groups
H hysteresis
S1 physical value
S2 input signal
1 current
t time

1. A method for momentary value-dependent actuation of a topological semiconductor switch for a power electronics system in real time, wherein
the topological semiconductor switch is divided into at least to groups of power semiconductors, which are formed from different semiconductor materials and/or different types of semiconductors,
the method comprising:
obtaining a momentary value for at least one variable physical value describing an operating state of the power electronics system, at predetermined times;
comparing the momentary value for the at least one variable physical value with a negative switching threshold and a positive switching threshold; and
determining, based on a result of the comparison, which of the at least two groups of power semiconductors are to be actuated in order to conduct output electricity.

2. The method according to claim 1, comprising:
refraining from switching from a current group of the at least two groups of power semiconductors to another group of the at least two groups of power semiconductors in response to the momentary value for the at least one physical value being between the negative and positive switching thresholds within a given time interval; and
switching from the current group of the at least two groups of power semiconductors to another group of the at least two groups of power semiconductors, or adding the other group of the at least two groups of power semiconductors to an active group of topological semiconductor switches to conduct the output electricity in response to the momentary value for the at least one physical value being below the negative switching threshold or being above the positive switching threshold.

3. The method according to claim 1,
wherein the at least one variable physical value is a current value represented as positive and negative current waves over time,
wherein the method comprises:
refraining from switching from a current group of the at least two groups of power semiconductors to another group of the at least two groups of power semiconductors in response to all of the momentary values for the at least one physical value being between the negative and positive switching thresholds within a period.

4. The method according to claim 1, wherein at least one of the negative or positive switching thresholds includes is a hysteresis near the at least one of the negative or positive switching thresholds.

5. The method according to claim 1, wherein the semiconductor materials comprise at least Si, SiC, or GaN, and/or wherein the types of semiconductors comprise at least MOSFET, IGBT, or JFET.

6. The method according to claim 1, comprising:
defining the negative and positive switching thresholds on a basis of an observed physical value.

7. The method according to claim 1, comprising;
determining switching signals for actuating the topological semiconductor switch; and
linking the momentary value for the at least one variable physical value to the switching signals to obtain an actuation signal with which at least one selected group of the at least two groups of power semiconductors is actuated.

8. The method according to claim 7, comprising:
forming a conjunctive logical link by linking the switching signals to the negative and positive switching thresholds.

9. An analog circuit for momentary value-dependent actuation of a topological semiconductor switch for a power electronics system in real time, wherein the topological semiconductor switch is divided into at least to groups of power semiconductors, which are formed from different semiconductor materials and/or different types of semiconductors, the analog circuit comprising:
circuitry configured to:
obtain a momentary value for at least one variable physical value describing an operating state of the power electronics system, at predetermined times;
compare the momentary value for the at least one variable physical value with a negative switching threshold and a positive switching threshold; and
determine, based on a result of the comparison, which of the at least two groups of power semiconductors are to be actuated in order to conduct output electricity.

10. An electronic module for actuating an electric drive in a vehicle, comprising:
an inverter comprising the analog circuit according to claim 9.

11. An electric drive for a vehicle, comprising:
the electronic module according to claim 10 for actuating the electric drive.

12. A vehicle comprising:
the electric drive according to claim 10.

13. The analog circuit according to claim 9,
wherein the circuitry is configured to:
refrain from switching from a current group of the at least two groups of power semiconductors to another group of the at least two groups of power semiconductors in response to the momentary value for the at least one physical value being between the negative and positive switching thresholds within a given time interval; and
switch from the current group of the at least two groups of power semiconductors to another group of the at least two groups of power semiconductors, or add the other group of the at least two groups of power semiconductors to an active group of topological semiconductor switches to conduct the output electricity in response to the momentary value for the at least one physical value being below the negative switching threshold or being above the positive switching threshold.

14. The analog circuit according to claim 9,
wherein the at least one variable physical value is a current value represented as positive and negative current waves over time,
wherein the circuitry is configured to:
refrain from switching from a current group of the at least two groups of power semiconductors to another group of the at least two groups of power semiconductors in response to all of the momentary values for the at least one physical value being between the negative and positive switching thresholds within a period.

15. The analog circuit according to claim 9,
wherein at least one of the negative or positive switching thresholds includes a hysteresis near the at least one of the negative or positive switching thresholds.

16. The analog circuit according to claim 9,
wherein the semiconductor materials comprise at least Si, SiC, or GaN, and/or wherein the types of semiconductors comprise at least MOSFET, IGBT, or JFET.

17. The analog circuit according to claim 9,
wherein the negative and positive switching thresholds are defined on a basis of an observed physical value.
